(19) United States
(12) Patent Application Publication
(10) Pub. No.: US 2014/0002971 A1
(43) Pub. Date: Jan. 2, 2014

(54) SURFACE CONTACT CARD HOLDER FOR ELECTRONIC DEVICE

(71) Applicants: SHENZHEN FUTAIHONG PRECISION INDUSTRY CO., LTD., Shenzhen (CN); FIH (HONG KONG) LIMITED, Kowloon (HK)

(72) Inventors: HUAN-CHANG CHUNG, Shindian (TW); HUA-XIANG LIANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/730,880

(22) Filed: Dec. 29, 2012

(30) Foreign Application Priority Data
Jun. 29, 2012 (CN) 201210221019X

(51) Int. Cl. H05K 5/02

(52) U.S. Cl. CPC H05K 5/0286; H05K 5/0217
USPC 361/679.01; 312/321.5

(57) ABSTRACT

A surface contact card holder includes a main body defining an entrance and a recess communicating with the entrance, a tray for receiving a surface contact card, and a door attached to an end of the tray and releasably received in the entrance. The tray is slidably received in the main body through the entrance. The door includes an operation board comprising elastic material and a fastening board attached to the operation board. The fastening board is movably connected to the tray. The operation board is positioned adjacent to the recess.

### BACKGROUND

1. Technical Field

The present disclosure relates to surface contact card holders for electronic devices.

2. Description of related art

Commonly, portable electronic devices such as mobile phones include a surface contact card holder for holding a surface contact card, such as a subscriber identity module (SIM) card therein.

Surface contact card holders of related art include a tray slidably assembled to the mobile phone. Although the surface contact card holders may be simple, it can be difficult and very fiddly for the surface contact card to be removed from the surface contact card holder.

Therefore, there is room for improvement within the art.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an exploded, isometric view of a surface contact card holder in accordance with an exemplary embodiment.

FIG. 2 is an exploded, isometric view of the surface contact card holder of FIG. 1 viewed from another angle.

FIG. 3 is an assembled, isometric view of the surface contact card holder of FIG. 1.

FIG. 4 is a cutaway view of the surface contact card holder of FIG. 3 in a first state (taken along line IV-IV).

FIG. 5 is a cutaway view of the surface contact card holder of FIG. 3 in a second state (taken along line IV-IV).

### DETAILED DESCRIPTION

The disclosed surface contact card holder holds and seats surface contact cards such as SIM cards, compact flash cards, multimedia cards, and others. The disclosed electronic device, shown in the exemplary embodiment as a mobile phone, can be a personal digital assistant, camera, recorder, or similar device within the scope of the disclosure.

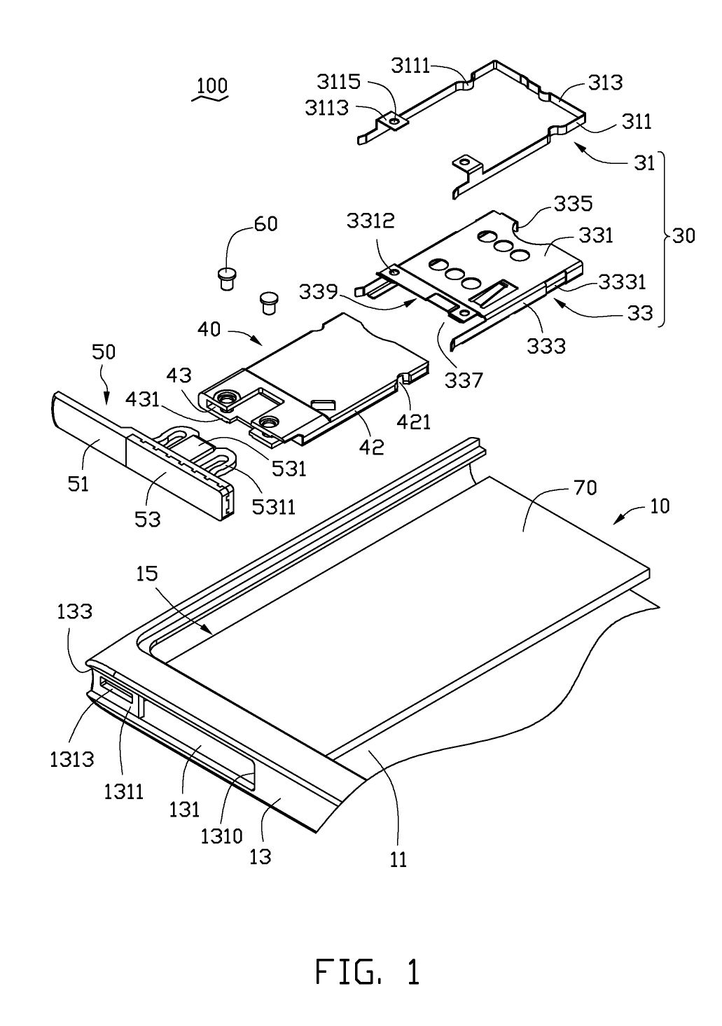

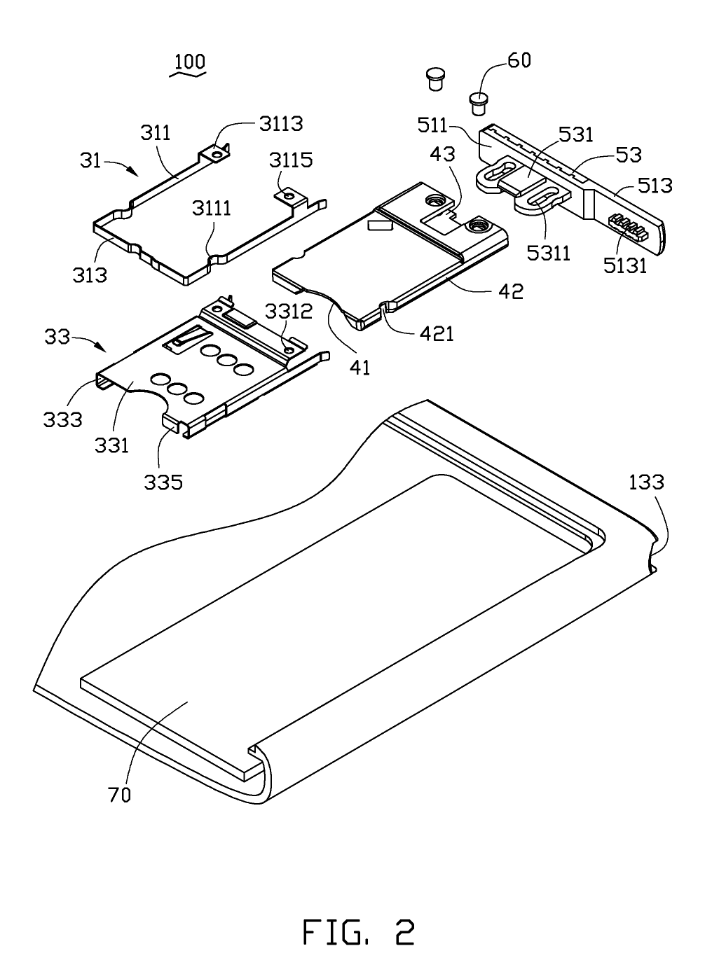

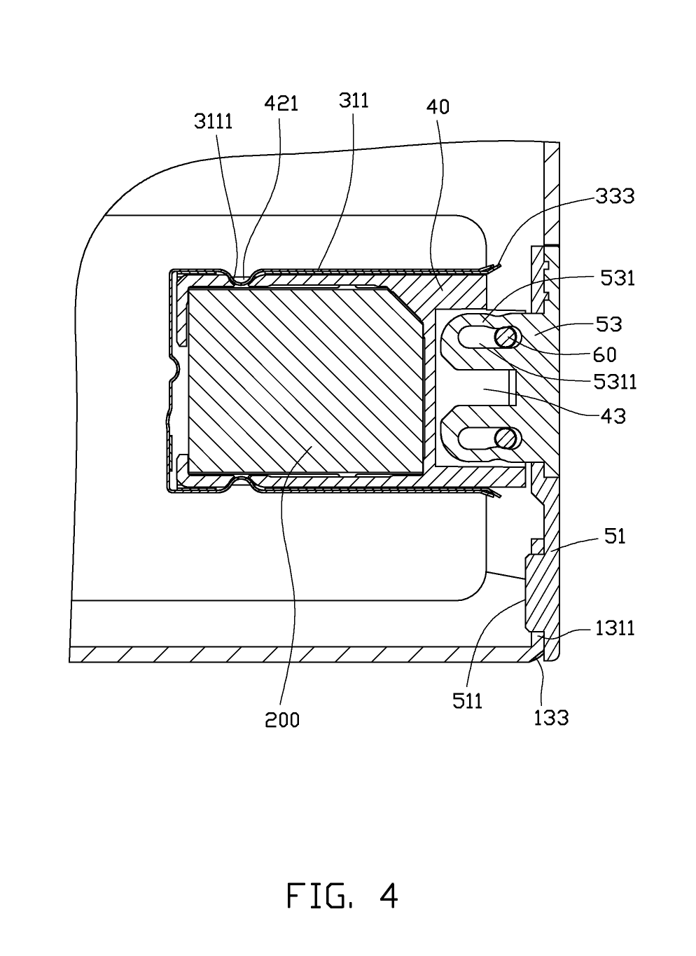

FIG. 1 and FIG. 2 show an exemplary embodiment of a surface contact card holder 100 configured for receiving a surface contact card 200 (see FIG. 4). The surface contact card holder 100 comprises a main body 10, a fastening assembly 30 assembled in the main body 10, a tray 40 detachably held by the fastening assembly 30, and a door 50 attached to the tray 40.

The main body 10 can be assembled in a housing of an electronic device or be integrally formed with the housing of the electronic device. In the exemplary embodiment, the main body 10 is integrally formed with the housing of the electronic device to be a portion of the housing. The main body 10 includes a bottom wall 11, a peripheral wall 13 protruding from an edge of the bottom wall 11, and a compartment 15 surrounded by the bottom wall 11 and the peripheral wall 13. The peripheral wall 13 defines an entrance 131 communicating with the compartment 15, thus forming an entrance sidewall 1310 surrounding the entrance 131. The door 50 is mounted to the entrance 131. A limiting portion 1311 protrudes from the entrance sidewall 1310 towards the entrance 131. When the door 50 is mounted in the entrance 131, the limiting portion 1311 blocks the door 50, so as to prevent the door 50 from dropping into the interior of the electronic device. A locking hole 1313 is defined through the limiting portion 1311. The locking hole 1313 is configured for locking the door 50. The peripheral wall 13 defines a recess 133 at an outer surface thereof. The recess 133 communicates with the entrance 131 and is proximate to the limiting portion 1311. The recess 133 facilitates a user's fingertip hooking or scratching the door 50 out from the recess 133, so as to pull out the door 50 from the entrance 131.

The fastening assembly 30 holds the tray 40 when the tray 40 is assembled in the main body 10. The fastening assembly 30 includes a latching member 31 for clamping the tray 40, and a receiving frame 33 for receiving the tray 40 therein.

The latching member 31 is substantially U-shaped, and includes two flexible arms 311 parallel to each other and a connecting portion 313 connecting with the two flexible arms 311. A portion of each flexible arm 311 bends towards the other flexible arm 311 to form a protrusion 3111. In the exemplary embodiment, each protrusion 3111 is adjacent to a first end of a flexible arm 311 which connects to the connecting portion 313. The two protrusions 3111 are opposite to each other and configured to resist and then to release the tray 40. In the exemplary embodiment, the two protrusions 3111 are arcuate. Each flexible arm 311 has a fastening portion 3113 perpendicularly extending therefrom and towards the other flexible arm 311. Each fastening portion 3113 is adjacent to a second end of a flexible arm 311 which is furthest from the connecting portion 313. Each fastening portion 3113 defines a first fastening hole 3115.

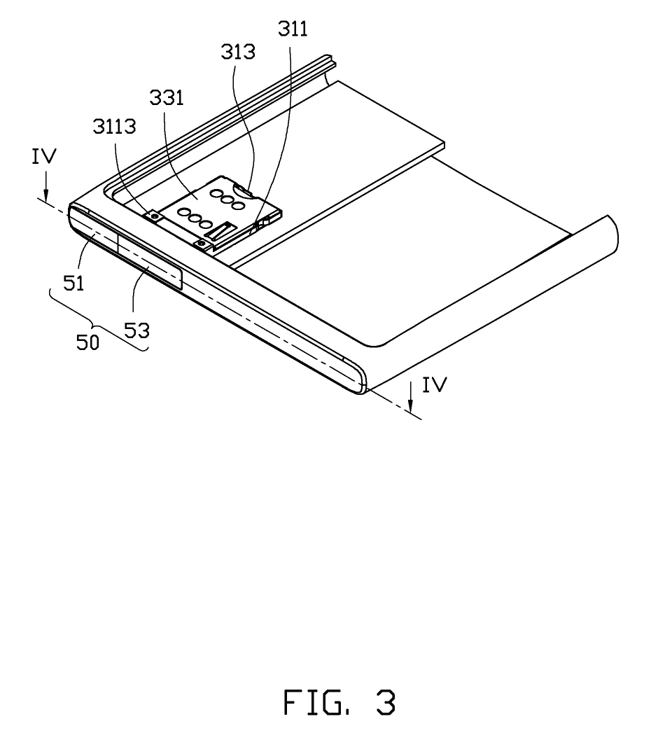

The receiving frame 33 includes a frame bottom wall 331, two opposite frame sidewalls 333, a frame end wall 335, and an opening 337. The two opposite frame sidewalls 333 and the frame end wall 335 extend from three adjacent edges of the frame bottom wall 331. The frame bottom wall 331, the two frame sidewalls 333, and the frame end wall 335 cooperatively surround a receiving space 339 for receiving the tray 40. The frame bottom wall 331 defines two second fastening holes 3312, corresponding to the two first fastening holes 3115. The opening 337 is opposite to the frame end wall 335 and communicates with the receiving space 339. Each frame sidewall 333 defines a through hole 3331. The latching member 31 abuts the periphery of the receiving frame 33 from an outside of the receiving frame 33. That is, each flexible arm 311 abuts against one of the two frame sidewalls 333, and the protrusions 3111 of the flexible arms 311 enter the receiving space 339 through the through holes 3331 of the frame sidewalls 333, so as to elastically clamp the tray 40 received in the receiving space 339. Each fastening portion 3113 abuts and is fastened to the frame bottom wall 331 by screws secured into the first and second fastening holes 3115, 3312, for example, thus securing the latching member 31 to the receiving frame 33 (see FIG. 3).

The fastening assembly 30 is received in the compartment 15. In the exemplary embodiment, the receiving frame 33 is attached to a circuit board 70 secured in the compartment 15, with the opening 337 of the receiving frame 33 facing the entrance 131. When the tray 40 is received in the receiving frame 33, the card 200 held in the tray 40 is electronically connected to the circuit board 70.

The tray 40 may be of metal and defines an accommodating recess 41 (shown in FIG. 2) at a side facing the bottom wall 11 of the main body 10, for accommodating the card 200. The tray 40 includes two tray sidewalls 42. Each tray sidewall 42 defines a notch 421 corresponding to one of the two through holes 3331 and one of the two protrusions 3111. The configuration of the notches 421 corresponds to the protrusions 3111. Each of the protrusions 3111 is releasably latched in one of the notches 421. The tray 40 is slidably received in the receiving frame 33. When the tray 40 is received in the receiving frame 33, the tray 40 is clamped between the two flexible arms 311, with the protrusions 3111 latched in the notches 421. The tray 40 further has a mounting slot 43 defined through an end facing the door 50. At least one fastening member 60 is disposed within the mounting slot 43 with two ends secured to two opposite mounting slot sidewalls 431 of the mounting slot 43. In the exemplary embodiment, the holder 100 has two fastening member 60, and each fastening member 60 is a screw or bolt.

The door 50 includes an operation board 51 and a fastening board 53 attached to the operation board 51. In the exemplary embodiment, the operation board 51 and the fastening board 53 are integrally formed to be one part by a double-shot molding process. The operation board 51 is made of elastic material, such as rubber. In one embodiment, the operation board 51 is made of thermoplastic polyurethane. The fastening board 53 is made of plastic.

The operation board 51 includes a bonding portion 511 and an operation portion 513 connected to the bonding portion 511. A retaining tab 5131 protrudes from the operation portion 513 and is located at a front side of the operation board 51 facing the entrance 131.

Referring to FIG. 2, the fastening board 53 bonds with the bonding portion 511. The fastening board 53 is located at a back side of the operation board 51 opposite to the front side and is coplanar with the operation portion 513. The fastening board 53 has a protruding block 531 extending through the bonding portion 511 and protruding towards the entrance 131. The protruding block 531 has at least one guiding hole 5311 corresponding to the at least one fastening member 60. In the exemplary embodiment, the fastening board 53 has two guiding holes 5311. The protruding block 531 is movably inserted in the mounting slot 43. Each fastening member 60 movably extends through one of the guiding holes 5311, thus allowing assembly of the door 50 to the tray 40. The guiding holes 5311 are substantially strip-shaped. During a process of drawing the door 50 out of the entrance 131, the fastening member 60 can move in the guiding holes 5311.

Referring to FIG. 4, when the door 50 is mounted in the entrance 131, the operation board 51 is accommodated in the entrance 131 and resists the limiting portion 1311. An end of the operation board 51 is proximate to the recess 133. The retaining tab 5131 is releasably latched in the locking hole 1313, so as to releasably lock the operation board 51 in the entrance 131.

Referring to FIG. 1 and FIG. 4, to assemble the surface contact card holder 100, the protruding block 531 of the door 50 is inserted into the mounting slot 43. Then, the fastening members 60 are inserted through the guiding holes 5311 and secured to the two opposite mounting slot sidewalls 431 of the mounting slot 43, thereby assembling the door 50 to the tray 40. The tray 40 is pushed into the receiving space 339 of the receiving frame 33 through the entrance 131. The tray 40 is clamped between the two flexible arms 311 of the latching member 31, with the protrusions 3111 latched in the notches 421 of the tray 40. The door 50 is received in the entrance 131, with the retaining tab 5131 latched in the locking hole 1313.

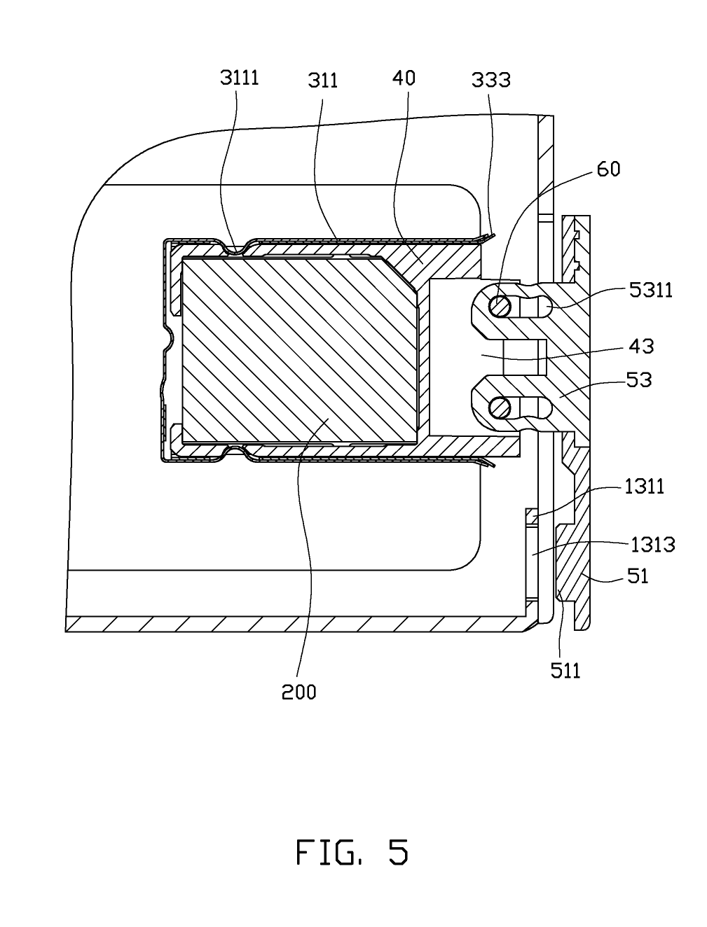

Referring to FIG. 3 through FIG. 5, to mount the card 200 into the holder 100 or to change the card 200, the operation portion 513 of the door 50 is lifted out of the entrance 131 from the recess 133. The door 50, along with the tray 40, can be drawn out from the main body 10 by pulling on the operation portion 513. The card 200 can be inserted into the accommodating recess 41 of the tray 40, or can be taken out to be changed. To close the holder 100, the tray 40 is pushed into the receiving space 339 until the two protrusions 3111 of the latching member 31 latch in the two notches 421 of the tray 40. The door 50 is pushed to be received in the entrance 131, with the retaining tab 5131 latched in the locking hole 1313.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A surface contact card holder, comprising:
a main body, the main body defines an entrance and a recess communicating with the entrance;
a tray for receiving a surface contact card, the tray is slidably received in the main body through the entrance; and
a door attached to an end of the tray and releasably received in the entrance, the door comprises an operation board comprising elastic material and a fastening board attached to the operation board, the fastening board is movably connected to the tray, and the operation board is positioned adjacent to the recess.

2. The holder as claimed in claim 1, wherein the operation board includes a bonding portion and an operation portion connected to the bonding portion; and the fastening board bonds with the bonding portion and is located at a back side of the operation board away from the entrance.

3. The holder as claimed in claim 2, wherein a retaining tab protrudes from the operation portion and is located at a front side of the operation board facing the entrance; the main body has an entrance sidewall surrounding the entrance; a limiting portion protrudes from the entrance sidewall towards the entrance; a locking hole is defined through the limiting portion; and the retaining tab is releasably latched in the locking hole.

4. The holder as claimed in claim 1, wherein the tray has a mounting slot defined through an end facing the door; at least one fastening member is disposed within the mounting slot with two ends secured to two opposite mounting slot sidewalls of the mounting slot; the fastening board has a protruding block protruding towards the entrance; the protruding block has at least one guiding hole corresponding to the at least one fastening member; the protruding block is movably inserted in the mounting slot; and the at least one fastening member movably extends through the at least one guiding hole, thus assembling the door to the tray.

5. The holder as claimed in claim 1, further comprising a fastening assembly; wherein the fastening assembly comprises a latching member; the latching member comprises two flexible arms parallel to each other and a connecting portion connecting with the two flexible arms; a portion of each flexible arm bends towards another one of the two flexible arms to form a protrusion; the tray has two tray sidewalls; each of the two tray sidewalls defines a notch; and each of the two protrusions is releasably latched in one of the two notches.

6. The holder as claimed in claim 5, wherein the fastening assembly further comprises a receiving frame for receiving the tray; and the latching member abuts a periphery of the receiving frame from an outside of the receiving frame.

7. The holder as claimed in claim 6,wherein the receiving frame comprises a frame bottom wall, two opposite frame sidewalls, a frame end wall, and an opening; the two opposite frame sidewalls and the frame end wall extend from three adjacent edges of the frame bottom wall; the frame bottom wall, the two frame sidewalls, and the frame end wall cooperatively surround an receiving space for receiving the tray; the opening is opposite to the frame end wall and communicates with the receiving space; and the opening is configured for the tray entering the receiving space therefrom.

8. The holder as claimed in claim 7, wherein each of the two frame sidewalls defines a through hole; each of the two flexible arms abuts against one of the two frame sidewalls; and the protrusions of the two flexible arms enter the receiving space through the through holes, to elastically clamp the tray received in the receiving space.

9. The holder as claimed in claim 7, wherein each of the two flexible arms further has a fastening portion perpendicularly extending therefrom and towards the other flexible arm; and the fastening portions are fastened to the frame bottom wall.

10. The holder as claimed in claim 1, wherein when the door is received in the entrance and an end of the operation board is proximate to the recess.

11. An electronic device comprising a surface contact card holder, the surface contact card holder mounted on the electronic device and comprising:
a main body, the main body defines an entrance and a recess communicating with the entrance;
a tray for receiving a surface contact card, the tray is slidably received in the main body through the entrance; and
a door attached to an end of the tray and releasably received in the entrance, the door comprises an operation board comprising elastic material and a fastening board attached to the operation board, the fastening board is movably connected to the tray, and the operation board is positioned adjacent to the recess.

12. The electronic device as claimed in claim 11, wherein the operation board includes a bonding portion and an operation portion connected to the bonding portion; and the fastening board bonds with the bonding portion and is located at a back side of the operation board away from the entrance.

13. The electronic device as claimed in claim 12, wherein a retaining tab protrudes from the operation portion and is located at a front side of the operation board facing the entrance; the main body has an entrance sidewall surrounding the entrance; a limiting portion protrudes from the entrance sidewall towards the entrance; a locking hole is defined through the limiting portion; and the retaining tab is releasably latched in the locking hole.

14. The electronic device as claimed in claim 11, wherein the tray has a mounting slot defined through an end facing the door; at least one fastening member is disposed within the mounting slot with two ends secured to two opposite mounting slot sidewalls of the mounting slot; the fastening board has a protruding block protruding towards the entrance; the protruding block has at least one guiding hole corresponding to the at least one fastening member; the protruding block is movably inserted in the mounting slot; and the at least one fastening member movably extends through the at least one guiding hole, thus assembling the door to the tray.

15. The electronic device as claimed in claim 11, further comprising a fastening assembly; wherein the fastening assembly comprises a latching member; the latching member comprises two flexible arms parallel to each other and a connecting portion connecting with the two flexible arms; a portion of each flexible arm bends towards another one of the two flexible arms to form a protrusion; the tray has two tray sidewalls; and each of the two tray sidewalls defines a notch; and each of the two protrusions is releasably latched in one of the two notches.

16. The electronic device as claimed in claim 15, wherein the fastening assembly further comprises a receiving frame for receiving the tray; and the latching member abuts a periphery of the receiving frame from an out side of the receiving frame.

17. The electronic device as claimed in claim 16, wherein the receiving frame comprises a frame bottom wall, two opposite frame sidewalls, a frame end wall, and an opening; the two opposite frame sidewalls and the frame end wall extend from three adjacent edges of the frame bottom wall; the frame bottom wall, the two frame sidewalls, and the frame end wall cooperatively surround an receiving space for receiving the tray; the opening is opposite to the frame end wall and communicates with the receiving space; and the opening is configured for the tray entering the receiving space therefrom.

18. The electronic device as claimed in claim 17, wherein each of the two frame sidewalls defines a through hole; each of the two flexible arms abuts against one of the two frame sidewalls; and the protrusions of the two flexible arms enter the receiving space through the through holes, to elastically clamp the tray received in the receiving space.

19. The electronic device as claimed in claim 17, wherein each of the two flexible arms further has a fastening portion perpendicularly extending therefrom and towards the other flexible arm; and the fastening portions are fastened to the frame bottom wall.

20. The electronic device as claimed in claim 17, further comprising a circuit board secured in the main body; wherein the receiving frame is attached to the circuit board.
